(19) United States
(12) Patent Application Publication
(10) Pub. No.: US 2026/0239605 A1
(43) Pub. Date: Aug. 13, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Jaemoon KIM, Suwon-si (KR); JOONCHEOL KIM, Suwon-si (KR); Jieun KIM, Suwon-si (KR); Jinwoong KIM, Suwon-si (KR); Sohyeon BAE, Suwon-si (KR); Suyeon SON, Suwon-si (KR); Jiyoung LEE, Suwon-si (KR)

(21) Appl. No.: 19/322,153

(22) Filed: Sep. 8, 2025

(30) Foreign Application Priority Data
Feb. 10, 2025 (KR) 10-2025-0016644

(51) Int. Cl. H10B 12/00

(52) U.S. Cl. CPC H10B 12/482; H10B 12/02

(57) ABSTRACT

A semiconductor device includes a substrate including a cell block region, a first bit line extending on the cell block region in a first direction, and landing patterns extending in a second direction crossing the first direction. The landing patterns include a first landing pattern crossing the first bit line, and a second landing pattern spaced apart from the first landing pattern in the first direction. An end of the first bit line is located between the first landing pattern and the second landing pattern.

### CROSS-REFERENCE TO RELATED APPLICATIONS

This U.S. non-provisional patent application claims priority under 35 U.S.C. § 119 of Korean Patent Application No. 10-2025-0016644, filed on Feb. 10, 2025, the entire contents of which are hereby incorporated by reference.

### BACKGROUND

The present disclosure relates to a semiconductor, and more particularly, to a semiconductor device and a method for manufacturing the same.

Semiconductor devices are attracting attention as an important component in the electronics industry due to characteristics thereof such as miniaturization, multi-functionality, and/or low manufacturing cost. Semiconductor devices may be classified into semiconductor memory devices that store, for example, logic data, semiconductor logic devices that calculate and process the logic data, and hybrid semiconductor devices that include a memory component and a logic component.

Recently, with a high speed and low power consumption of an electronic apparatus, a high operation speed, a low operation voltage and/or the like are/is also required for the semiconductor device built therein. In order to satisfy such requirements, the semiconductor device becomes more highly-integrated, and much research for this is being carried out.

### SUMMARY

The present disclosure provides a semiconductor device with improved integration and a method for manufacturing the same.

The present disclosure also provides a semiconductor device with improved electrical characteristics and reliability.

A technical goal of the inventive concept is not limited to the goal mentioned above, and other technical goals that are not mentioned may be clearly understood from description below by those skilled in the art.

An embodiment of the inventive concept provides a semiconductor device including a substrate including a cell block region, a first bit line extending on the cell block region in a first direction, and landing patterns extending in a second direction crossing the first direction, wherein the landing patterns include a first landing pattern crossing the first bit line, and a second landing pattern spaced apart from the first landing pattern in the first direction, and an end of the first bit line is located between the first landing pattern and the second landing pattern.

In an embodiment of the inventive concept, a semiconductor device includes a substrate including a cell block region, a first bit line extending on the cell block region in a first direction, and landing patterns extending in a second direction crossing the first direction, wherein the landing patterns include a first landing pattern crossing the first bit line, and a second landing pattern spaced apart from the first landing pattern in the first direction, the first bit line includes a first end adjacent to the first landing pattern, the second landing pattern is spaced apart from the first end in the first direction, and the second landing pattern has a greater height than the first landing pattern.

In an embodiment of the inventive concept, a semiconductor device includes a substrate including a cell block region, a first bit line and a second bit line extending on the cell block region in a first direction, and being next to each other in a second direction crossing the first direction, landing patterns extending in the second direction, and a contact plug electrically connected to the second bit line, wherein the landing patterns include a first landing pattern crossing the first bit line and the second bit line, and a second landing pattern spaced apart from the first landing pattern in the first direction, the first bit line includes a first end adjacent to the first landing pattern, the second landing pattern is spaced apart from the first end in the first direction, and the second landing pattern is located between the first landing pattern and the contact plug.

In an embodiment of the inventive concept, a method for manufacturing a semiconductor device includes forming a first bit line extending in a first direction on a substrate including a cell block region, forming a word line crossing the first bit line, and forming landing patterns extending in a second direction crossing the first direction, wherein the landing patterns include a first landing pattern crossing the first bit line, and a second landing pattern spaced apart from the first landing pattern in the first direction, and an end of the first bit line is located between the first landing pattern and the second landing pattern.

In an embodiment, the method for manufacturing a semiconductor device may further include a landing insulating pattern interposed between the first landing pattern and the second landing pattern, wherein the end of the first bit line may vertically overlap the landing insulating pattern.

In an embodiment, a bottom surface of the landing insulating pattern may be located at a lower level than a bottom surface of the first landing pattern.

In an embodiment, the first landing pattern may have a smaller height than the second landing pattern.

In an embodiment, the method for manufacturing a semiconductor device may further include forming a bit line capping pattern on the first bit line, wherein the first landing pattern may vertically overlap the bit line capping pattern, and the second landing pattern may be spaced apart from the bit line capping pattern in the first direction.

In an embodiment, the forming of the landing patterns may include forming a landing pad layer on the cell block region, forming insulating holes by etching the landing pad layer, and filling the insulating holes with an insulating material.

In an embodiment, the etching of the landing pad layer may include forming a mask pattern on a landing pad layer, and performing an etching process by using the mask pattern as a mask, and the mask pattern may be located so as to vertically overlap a part in which the landing patterns are formed.

In an embodiment, the insulating holes may include a first insulating hole exposing the bit line capping pattern, and a second insulating hole exposing a poly portion, and the first insulating hole may have a shallower depth than the second insulating hole.

In an embodiment, the method for manufacturing a semiconductor device may further include forming a second bit line next to the first bit line in the second direction, forming a bit line pad connected to the second bit line, and forming a contact plug on the bit line pad, wherein the second bit line may be connected to the contact plug through the bit line pad, and the second landing pattern may be located between the first landing pattern and the contact plug.

In an embodiment, the second landing pattern may vertically overlap at least a portion of the bit line pad.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a diagram illustrating a substrate on which semiconductor devices according to embodiments of the inventive concept are integrated;

FIGS. 2A and 2B are enlarged diagrams corresponding to X1 of FIG. 1;

FIG. 3 is a diagram illustrating a cell block group region of FIGS. 2A and 2B;

FIG. 4 is a plan view illustrating a cell block region of FIG. 3 as a diagram illustrating a semiconductor device according to embodiments of the inventive concept;

FIG. 5A is a cross-sectional view corresponding to line A-A′ of FIG. 4;

FIG. 5B is a cross-sectional view corresponding to line B-B′ of FIG. 4;

FIG. 5C is a cross-sectional view corresponding to line C-C′ of FIG. 4;

FIG. 6A is a plan view illustrating a cell block region of FIG. 3 as a diagram illustrating a semiconductor device according to comparative examples of the inventive concept;

FIG. 6B is a cross-sectional view corresponding to line C-C′ of FIG. 6A; and

FIGS. 7A to 12C are diagrams illustrating a method for manufacturing a semiconductor device according to embodiments of the inventive concept.

### DETAILED DESCRIPTION

Hereinafter, embodiments according to the inventive concept will be described in more detail with reference to the accompanying drawings in order to more specifically describe the inventive concept.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “constant,” “flat,” etc. as used herein, are intended to encompass meanings that include typical variations resulting from conventional manufacturing processes and/or accommodate tolerances acceptable in the manufacturing process of the semiconductor device, unless the context or other statements indicate otherwise. For example, ‘same’ and ‘equal’ may encompass identicality or near identicality. The term “substantially” may be used herein to emphasize this meaning.

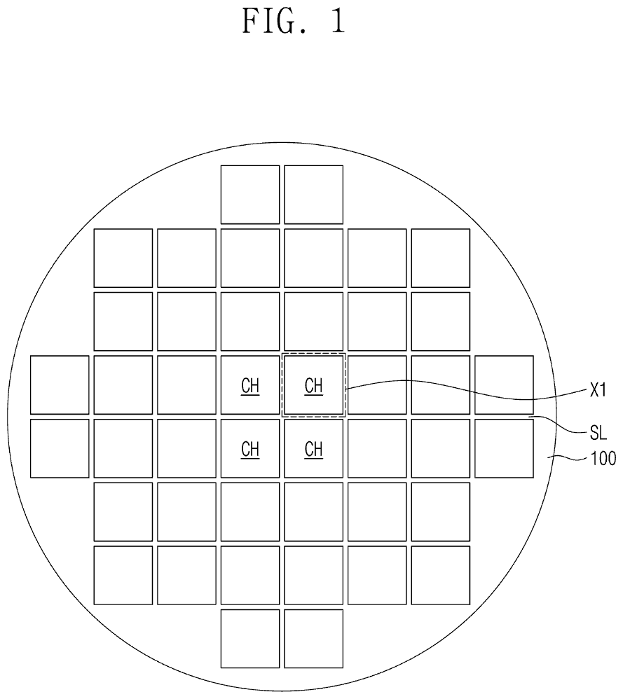

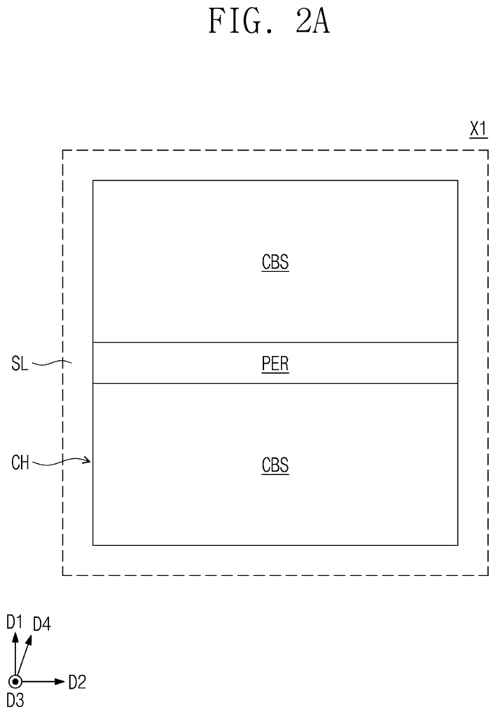

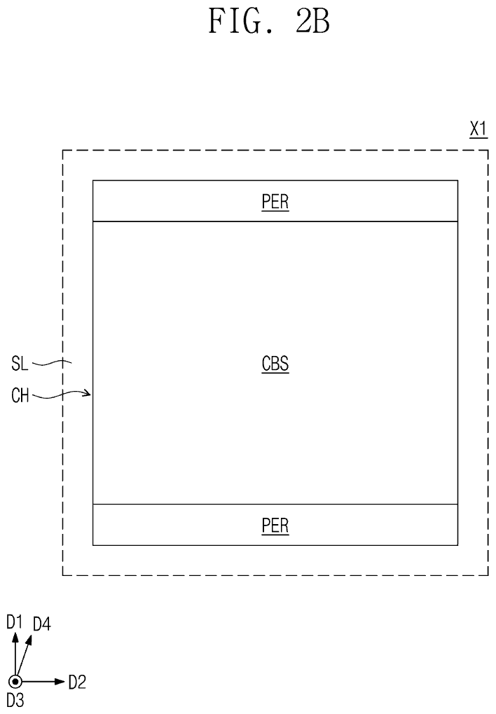

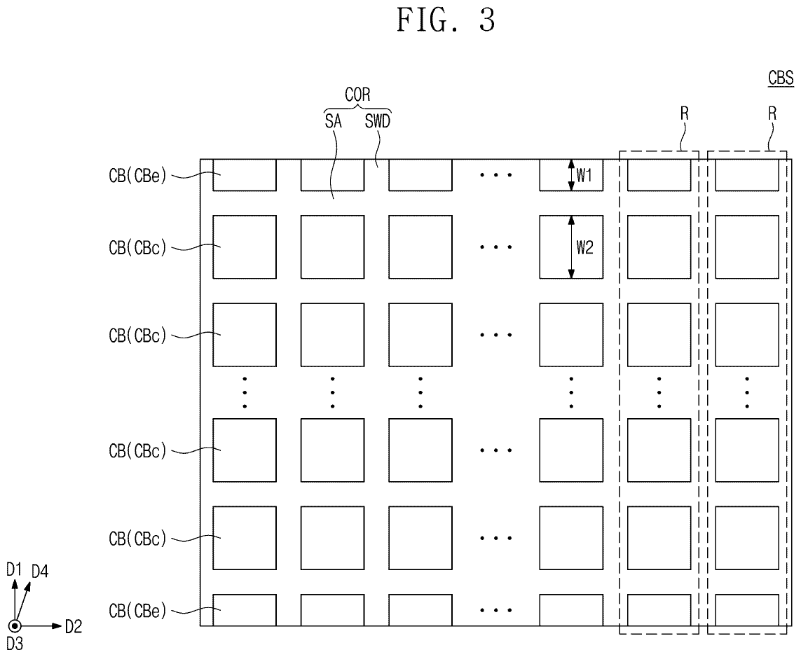

FIG. 1 is a diagram illustrating a substrate on which semiconductor devices according to embodiments of the inventive concept are integrated. FIGS. 2A and 2B are enlarged diagrams corresponding to X1 of FIG. 1. FIG. 3 is a diagram illustrating a cell block group region of FIGS. 2A and 2B.

Referring to FIGS. 1, 2A, 2B and 3, a substrate 100 may include chip regions CH on which semiconductor integrated circuits are located, and a scribe lane region SL between the chip regions CH. The substrate 100 may be any one of semiconductor substrates, for example, a silicon substrate, a germanium substrate, or a silicon-germanium substrate. In the present specification, each of the wordings, “A or B”, “at least one of A and B”, “at least one of A or B”, “A, B or C”, “at least one of A, B and C” and “at least one of A, B or C” may include any one of items listed together with a corresponding wording thereamong, or all possible combinations thereof.

The chip regions CH may be two-dimensionally arranged along a first direction D1 and a second direction D2 crossing (for example, perpendicular to) the first direction D1. The first and second directions D1 and D2 may be each parallel to a lower surface of the substrate 100. Each of the chip regions CH may be surrounded by the scribe lane region SL.

The scribe lane region SL may include a plurality of first scribe lane regions extending in the first direction D1 and a plurality of second scribe lane regions crossing the first scribe lane regions and extending in the second direction D2. The scribe lane region SL may include a cutting lane region cut by a sawing or cutting machine, and edge lane regions between the chip regions CH and the cutting lane region. The edge lane regions may respectively surround the chip regions CH. For example, on a plan view, the cutting lane region may be interposed between the chip regions CH next to each other, and the edge lane regions may be interposed between the chip regions CH and the cutting lane region.

Semiconductor devices may be provided on the chip regions CH of the substrate 100. For example, semiconductor memory devices such as a dynamic random access memory (DRAM), a static random access memory (SRAM), a NAND flash memory and a resistive random access memory (RRAM) may be provided on the chip regions CH. For another example, a processor such as a microelectromechanical system (MEMS) device, an optoelectronic device, a CPU or a DSP may be provided on the chip regions CH. For another example, standard cells including a semiconductor device such as a logic sum gate or a logic product gate may be provided on the chip regions CH of the substrate 100.

Each of the chip regions CH may include a peripheral region PER and a cell block group region CBS. Peripheral circuits may be provided on the peripheral region PER. The peripheral circuits may perform command/address, power generation and/or data input-output (DQ).

Each of the chip regions CH may include a singular peripheral region PER or a plurality of peripheral regions PER, and may include a singular cell block group region CBS or a plurality of cell block group regions CBS. For example, as illustrated in FIG. 2A, the chip region CH may include a pair of cell block group regions CBS next to each other in the first direction D1 and the peripheral region PER therebetween. For another example, as illustrated in FIG. 2B, the chip region CH may include a pair of peripheral regions PER next to each other in the first direction D1 and the cell block group region CBS therebetween. However, this is an example, and the inventive concept is not limited thereto.

The cell block group region CBS may be next to the surrounding region PER and SL in the first direction D1. The surrounding region PER and SL may include the peripheral region PER and the scribe lane region SL. For example, as illustrated in FIG. 2A, the cell block group region CBS may be interposed between the peripheral region PER and the scribe lane region SL (specifically, the edge lane region) next to each other in the first direction D1. For another example, as illustrated in FIG. 2B, the cell block group region CBS may be interposed between the peripheral regions PER next to each other in the first direction D1.

Referring to FIG. 3, the cell block group region CBS may include a plurality of cell block regions CB and core regions COR surrounding the same. Core circuits may be provided on the core region COR. The core circuits may sense/control bit lines BL and/or word lines WL on the cell block region CB. For example, the core circuits may include sense amplifier circuits SA that sense the bit lines BL and sub-word line driver circuits SWD that control the word lines WL. The sense amplifier circuits SA may face each other in the first direction D1 with the cell block regions CB therebetween. The sub-word line driver circuits SWD may face each other in the second direction D2 with the cell block regions CB therebetween.

The cell block regions CB may be disposed spaced apart from each other in the first and second directions D1 and D2. For example, the cell block regions CB may include a cell block column R disposed along the first direction D1, and a plurality of cell block columns R may be spaced apart from each other in the second direction D2. The cell block column R may include edge cell block regions CBe disposed at both ends along the first direction D1, and center cell block regions CBc therebetween. The edge cell block regions CBe may be disposed on edges along the first direction D1 of the cell block group region CBS. The edge cell block regions CBe may be more adjacent to the surrounding region PER and SL than the center cell block regions CBc. For example, one surface of the edge cell block region CBe may be adjacent to the surrounding region PER and SL, and the other surface opposed to the one surface of the edge cell block regions CBe may be adjacent to the core region COR. The center cell block regions CBc may be surrounded by the core region COR.

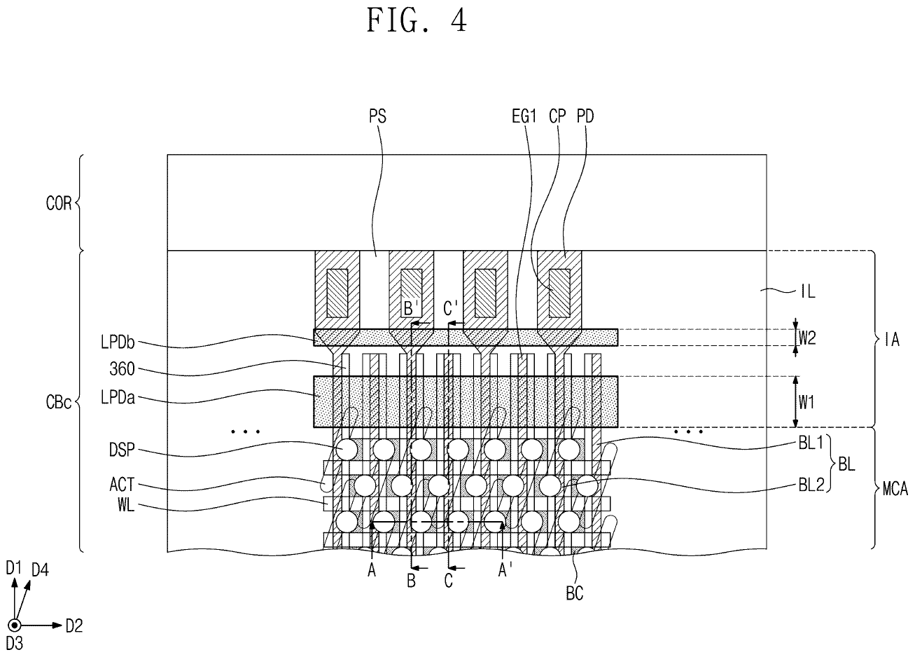

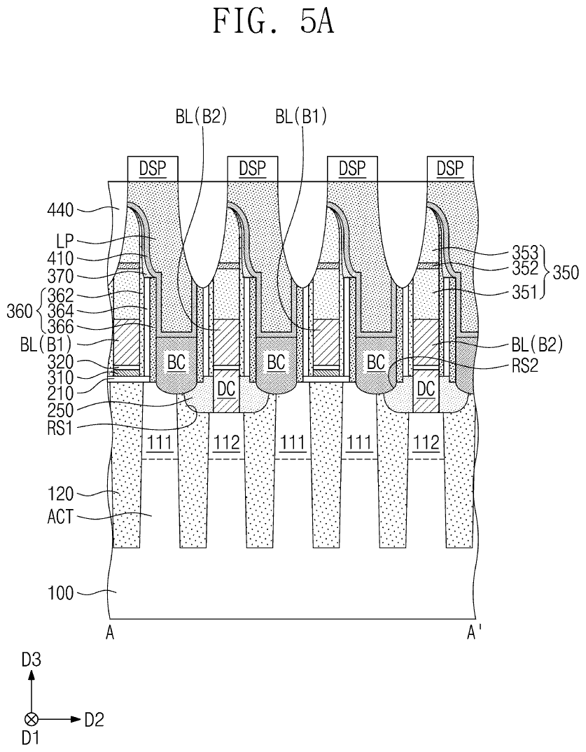

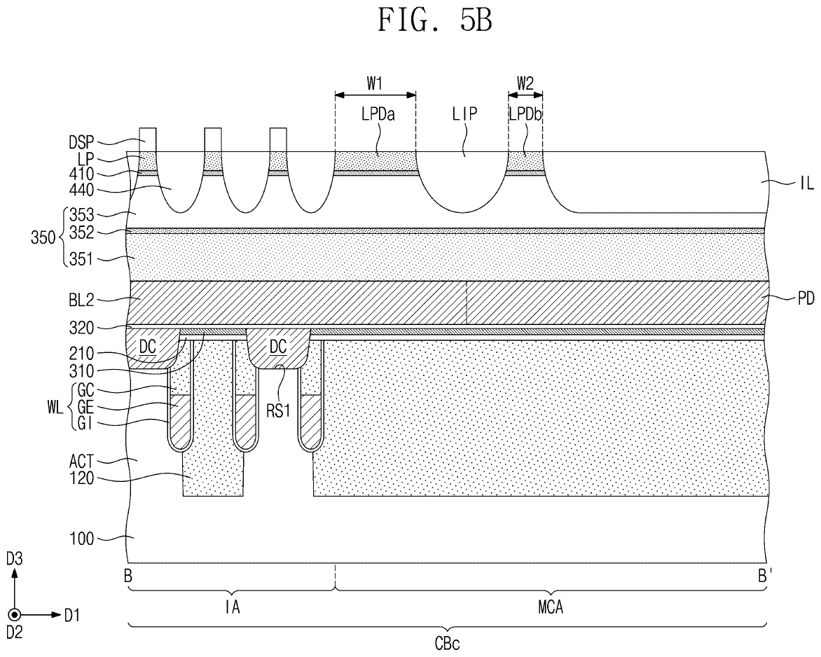

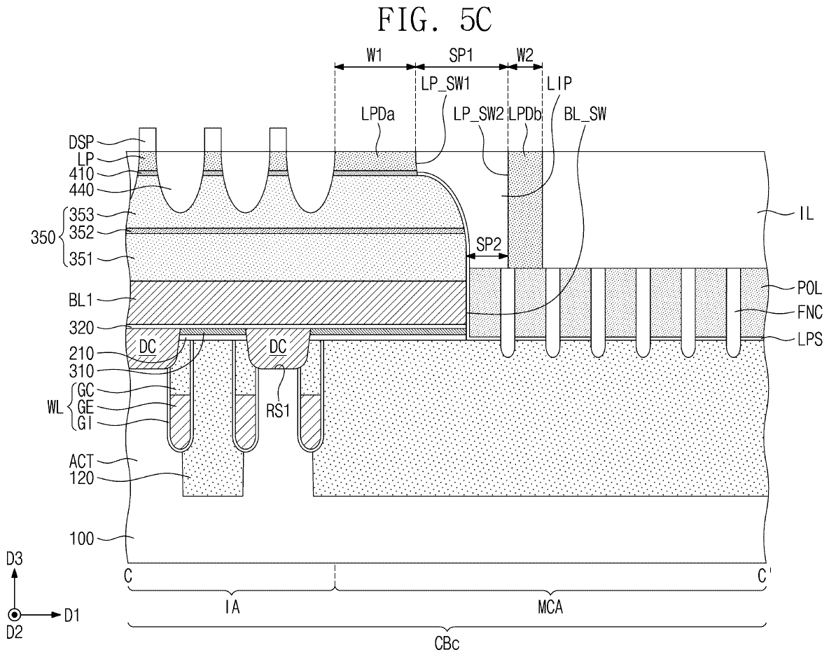

FIG. 4 is a plan view illustrating a cell block region of FIG. 3 as a diagram illustrating the semiconductor device according to embodiments of the inventive concept. FIG. 5A is a cross-sectional view corresponding to line A-A′ of FIG. 4. FIG. 5B is a cross-sectional view corresponding to line B-B′ of FIG. 4. FIG. 5C is a cross-sectional view corresponding to line C-C′ of FIG. 4. Referring to FIGS. 3 to 5C, an element separation pattern 120 may be disposed in the substrate 100, and active patterns ACT may be defined. The active patterns ACT may be provided on the cell block regions CB of the substrate 100. The active patterns ACT may protrude in a third direction D3 vertical to a lower surface of the substrate 100. For example, the active patterns ACT may be parts of the substrate 100 surrounded by the element separation pattern 120. For convenience of description, as long as there is no separate description, it is defined in the present specification that the substrate 100 is referred to as the other portion of the substrate 100 except for the active patterns ACT. The active patterns ACT may be disposed spaced apart from each other in the first direction D1 and the second direction D2. Each of the active patterns ACT may have a shape of a separated island (or a single body), and may have a form of a bar long in a fourth direction D4. The fourth direction D4 may be parallel to the lower surface of the substrate 100, and may cross the first and second directions D1 and D2. The element separation pattern 120 may include an insulating material, for example, at least one of silicon oxide, silicon nitride or a combination thereof. The element separation pattern 120 may be a singular layer composed of a singular material or a composite layer including at least two materials.

Each of the active patterns ACT may include a pair of edge portions 111 and a center portion 112. The pair of edge portions 111 may be respectively both end portions (or ends) of the active pattern ACT with respect to the fourth direction D4. The center portion 112 may be a portion of the active pattern ACT interposed between the pair of edge portions 111, and specifically, may be a portion of the active pattern ACT interposed between a pair of word lines WL to be described later. The pair of edge portions 111 and the center portion 112 may be doped with an impurity (charge carrier dopant), for example, an N-type impurity or a P-type impurity.

The word line WL may be provided in the active patterns ACT. The word line WL may be provided in plurality. The word lines WL may extend in the second direction D2, and may be spaced apart from each other in the first direction D1. The word lines WL may be disposed in the active patterns ACT and trenches provided in the element separation pattern 120. For example, a pair of word lines WL next to each other in the first direction D1 may cross one active pattern ACT.

Each of the word lines WL may include a gate electrode GE, a gate dielectric pattern GI and a gate capping pattern GC. The gate electrode GE may penetrate the active patterns ACT and the element separation pattern 120 in the second direction D2. The gate dielectric pattern GI may be interposed between the gate electrode GE and the active patterns ACT and between the gate electrode GE and the element separation pattern 120. The gate capping pattern GC may cover an upper surface of the gate electrode GE.

A buffer pattern 210 may be disposed on the substrate 100. The buffer pattern 210 may cover the active patterns ACT, the element separation pattern 120 and the word lines WL. For example, the buffer pattern 210 may include at least one of silicon oxide, silicon nitride, silicon oxynitride or a combination thereof. The buffer pattern 210 may be a singular layer composed of a singular material, or a composite layer including at least two materials.

A bit line contact DC may be provided on each of the active patterns ACT, and may be provided in plurality. The bit line contacts DC may be respectively connected to the center portions 112 of the active patterns ACT. In the present specification, an expression such as “A is connected to B” may include not only a meaning that A is in contact with B but also a meaning that A is not in contact with B but A is electrically connected to B. The bit line contacts DC may be spaced apart from each other in the first and second directions D1 and D2. The bit line contacts DC may be respectively interposed between the active patterns ACT and the bit lines BL to be described later. The bit line contact DC may connect a corresponding bit line BL among the bit lines BL and the center portion 112 of a corresponding active pattern ACT.

The bit line contacts DC may be respectively disposed in first recess regions RS1. The first recess regions RS1 may be provided on upper portions of the active patterns ACT and on the element separation pattern 120 adjacent to the upper portions of the active patterns ACT. The first recess regions RS1 may be spaced apart from each other in the first and second directions D1 and D2.

Referring to FIG. 4, the bit line BL may be provided on the cell block region CB. The bit line BL may be provided in plurality. Each of the bit lines BL may extend lengthwise in the first direction D1, and may be spaced apart from each other in the second direction D2. The bit line BL may include a metal material. For example, the bit line BL may include at least one of tungsten, rubidium. molybdenum, titanium or a combination thereof. An item, layer, or portion of an item or layer described as extending “lengthwise” in a particular direction has a length in the particular direction and a width perpendicular to that direction, where the length is greater than the width.

The bit line BL may include a first bit line BL1 and a second bit line BL2 next to each other in the second direction D2. Each of the first bit line BL1 and the second bit line BL2 may include a metal material (for example, Ti, Mo, W, Cu, Al, Ta, Ru, Ir or the like). For example, the first bit line BL1 and the second bit line BL2 may include the same material as each other.

One end of the second bit line BL2 may be connected to a bit line pad PD. In addition, one end of the first bit line BL1 may not be connected to the bit line pad PD. The bit line pad PD may electrically connect the bit line BL to a contact plug CP to be described later. A width in the second direction D2 of the bit line pad PD may be greater than a width in the second direction D2 of the bit line BL. The bit line pad PD may have a hammer head profile. The bit line pad PD may include the same material as the bit line BL, and may be connected to the second bit line BL2 without a boundary surface.

Referring to FIGS. 3 to 5C, a polysilicon pattern 310 may be provided between the bit line BL and the buffer pattern 210, and between the bit line contacts DC next to each other in the first direction D1. The polysilicon pattern 310 may be provided in plurality. For example, each of a plurality of polysilicon patterns 310 may be spaced apart from each other in the first direction D1 and the second direction D2. An upper surface of the polysilicon pattern 310 may be located at the substantially same height as an upper surface of the bit line contact DC, and may be coplanar with each other. The polysilicon pattern 310 may include doped polysilicon.

Referring to FIGS. 4, 5B and 5C, the cell block region CB may include a memory cell array region MCA and an interface region IA, and the interface region IA may be adjacent to the edge of the memory cell array region MCA. The memory cell array region MCA may be a region in which unit cells are arranged in a regularly repeating pattern to form an array. Two adjacent memory cell array regions MCA may be spaced apart from each other by a region where this periodicity is interrupted, thereby allowing the memory cell array regions MCA to be clearly distinguished from each other.

The region in which this repetition is interrupted (i.e., the area located between two adjacent memory cell array regions MCA) may be the interface region IA and/or the core region COR. For example, the interface region IA may be configured to electrically connect the first bit line BL1 to other functional regions (e.g., the sense amplifier circuits SA) by a conductive pattern such as the contact plug CP and the bit line pad PD.

In some embodiments, each cell block region CB may include a plurality of interface regions IA. For example, the first bit line BL1 may be electrically connected to a first sense amplifier circuit SA through a first interface region IA as illustrated in the drawings, and the second bit lines BL2 may be electrically connected to a second sense amplifier circuit through another interface region (not shown in the drawings). The two interface regions may be located at opposite sides of a corresponding cell block region CB.

Referring to FIGS. 3 to 5C, a first barrier pattern 320 may be provided between the bit line BL and the bit line contact DC, between the bit line BL and the polysilicon pattern 310, and between the bit line pad PD and the polysilicon pattern 310. The first barrier patterns 320 may extend along the bit lines BL in the first direction D1, and may be spaced apart from each other in the second direction D2. The first barrier pattern 320 may include conductive metal nitride such as titanium nitride or tantalum nitride. A first ohmic pattern (not shown) may be further interposed between the bit line BL and the bit line contact DC and between the bit line BL and the polysilicon pattern 310. The first ohmic pattern may include metal silicide.

A bit line capping pattern 350 may be provided on an upper surface of the bit line BL. The bit line capping pattern 350 may be provided in plurality. The bit line capping patterns 350 may respectively extend along corresponding bit lines BL in the first direction D1, and may be spaced apart from each other in the second direction D2. The bit line capping pattern 350 may vertically overlap the bit line BL. The bit line capping pattern 350 may be composed of a singular layer or a multiple layer. For example, the bit line capping pattern 350 may include a first capping pattern 351, a second capping pattern 352 and a third capping pattern 353 sequentially stacked. The first to third capping patterns 351, 352 and 353 may include silicon nitride. For another example, additional capping patterns such as fourth and fifth capping patterns (not shown) may be further included.

A spacer structure 360 may be provided on a side surface of the bit line BL and a side surface of the bit line capping pattern 350. The spacer structure 360 may cover the side surface of the bit line BL and the side surface of the bit line capping pattern 350. A bit line trench BTR may be provided between the bit lines BL, and the spacer structure 360 may cover an inner side surface of the bit line trench BTR (see FIG. 4). The bit line trench BTR and the spacer structure 360 may extend along the first direction D1. The spacer structure 360 may be provided in plurality.

The spacer structure 360 may include a plurality of spacers. For example, the spacer structure 360 may include a first spacer 362, a second spacer 364 and a third spacer 366. The third spacer 366 may be provided on the side surface of the bit line BL and the side surface of the bit line capping pattern 350. The first spacer 362 may be interposed between the bit line BL and the third spacer 366, and between the bit line capping pattern 350 and the third spacer 366. The second spacer 364 may be interposed between the first spacer 362 and the third spacer 366. For example, each of the first to third spacer structures 362, 364 and 366 may include at least one of silicon oxide, silicon nitride, silicon oxynitride or a combination thereof. For another example, the second spacer structure 364 may include a kind of air gap spacing the first and third spacer structures 362 and 366 apart from each other.

A buried insulating pattern 250 may fill each of the first recess regions RS1. The buried insulating pattern 250 may fill an inside of the first recess region RS1. For example, the buried insulating pattern 250 may cover an inner surface of the first recess region RS1 and at least a portion of a side surface of the bit line contact DC (for example, at least a portion of the side surface of the bit line contact DC in the first recess region RS1). The buried insulating pattern 250 may include at least one of silicon oxide, silicon nitride or a combination thereof. The buried insulating pattern 250 may be a singular layer composed of a singular material, or a composite layer including at least two materials.

A capping spacer 370 may be located on the spacer structure 360. The capping spacer 370 may cover an upper portion of a side surface of the spacer structure 360. For example, the capping spacer 370 may include silicon nitride.

A storage node contact BC may be provided between the bit lines BL next to each other. For example, the storage node contact BC may be interposed between the spacer structures 360. The storage node contact BC may be provided in plurality, and the storage node contacts BC may be spaced apart from each other in the first and second directions D1 and D2. The storage node contacts BC may be spaced apart from each other in the first direction D1 by fence patterns FN on the word lines WL. For example, some of the storage node contacts BC may be interposed between the first bit line BL1 and the second bit line BL2. The storage node contact BC may include a conductive material. For example, the storage node contact BC may include at least one of polysilicon (for example, polysilicon including an impurity) or a metal material (for example, Ti, Mo, W, Cu, Al, Ta, Ru, Ir or the like).

A second barrier pattern 410 may conformally cover the spacer structure 360 and the storage node contact BC. The second barrier pattern 410 may include metal nitride such as titanium nitride or tantalum nitride. A second ohmic pattern (not shown) may be further interposed between the second barrier pattern 410 and the storage node contact BC. The second ohmic pattern may include metal silicide.

A landing pad LP may be provided on the storage node contact BC. The landing pad LP may be provided in plurality, and the landing pads LP may be spaced apart from each other in the first and second directions D1 and D2. The landing pad LP may be connected to a corresponding storage node contact BC. The landing pad LP may cover an upper surface of the bit line capping pattern 350. A lower region of the landing pad LP may vertically overlap the storage node contact BC. An upper region of the landing pad LP may be shifted from the lower region thereof in the second direction D2. The landing pad LP may include a metal material such as tungsten, titanium or tantalum.

A filling pattern 440 may surround the landing pad LP. The filling pattern 440 may be interposed between the landing pads LP next to each other. On a plan view, the filling pattern 440 may have a form of a mesh including holes penetrated by the landing pads LP. For example, the filling pattern 440 may include at least one of silicon oxide, silicon nitride, silicon oxynitride or a combination thereof. For another example, the filling pattern 440 may include an empty space (e.g., an air gap) including an air layer.

A contact plug CP may be provided on the bit line pad PD. The contact plug CP may penetrate the filling pattern 440 and the bit line capping pattern 350 (for example, the first capping pattern 351) in the third direction D3, and may be connected to the bit line pad PD. The contact plug CP may include the same material as the landing pad LP.

Contact wires may be connected to the contact plug CP on the filling pattern 440. The contact wires may include at least one wire layer. The contact wires may be connected to core circuits on the core region COR. The bit lines BL may be connected to the core circuits (for example, the sense amplifier circuits SA) through the bit line pad PD, the contact plug CP and the contact wires.

A data storage pattern DSP may be provided on the landing pad LP. The data storage pattern DSP may be provided in plurality, and the data storage patterns DSP may be spaced apart from each other in the first and second directions D1 and D2. The data storage pattern DSP may be connected to a corresponding edge portion 111 through a corresponding landing pad LP and a corresponding storage node contact BC.

For example, the data storage pattern DSP may be a capacitor including a lower electrode, a dielectric layer and an upper electrode. In this case, a semiconductor memory device according to the inventive concept may be a dynamic random access memory (DRAM). For another example, the data storage pattern DSP may include a magnetic tunnel junction pattern. In this case, the semiconductor memory device according to the inventive concept may be a magnetic random access memory (MRAM). For another example, the data storage pattern DSP may include a phase-change material or a variable resistance material. In this case, the semiconductor memory device according to the inventive concept may be a phase-change random access memory (PRAM) or a resistive random access memory (ReRAM). However, these are examples, and the inventive concept is not limited thereto, and the data storage pattern DSP may include various structures and/or materials capable of storing a data.

The landing pad LP will be described in more detail with reference to FIGS. 4 to 5C again.

A poly portion POL and a fence portion FNC may be provided on an edge part of the cell block region CBc. The poly portion POL and the fence portion FNC may be each provided in plurality. The poly portion POL may not be directly connected to the bit line. The poly portion POL may be a part connected to the landing pad LP. The poly portion POL may include a conductive material. The poly portion POL may include a part not connected to a real circuit.

The fence portion FNC may be provided between the poly portions POL adjacent to each other. The fence portion FNC may vertically penetrate the poly portion POL. The fence portions FNC adjacent to each other may be disposed spaced apart from each other in the first direction D1. The fence portion FNC may include an insulating material to block electrical connection between the poly portions POL adjacent to each other.

An interlayered insulating layer IL may be provided on the poly portion POL and the fence portion FNC. The interlayered insulating layer IL may include at least one of silicon oxide, silicon nitride, a low-dielectric material or a combination thereof. The low-dielectric material means a material having a lower dielectric constant than silicon oxide.

Landing patterns LPDa and LPDb may be provided on the cell block region CBc. The landing patterns LPDa and LPDb may be provided on an edge part of the cell block region CBc. The landing patterns LPDa and LPDb may be dummy patterns formed on the edge part when the landing pad LP is formed. The landing patterns LPDa and LPDb may cross the bit lines BL to extend in the second direction D2. The landing patterns LPDa and LPDb may include a first landing pattern LPDa and a second landing pattern LPDb spaced apart from each other in the first direction D1. The landing patterns LPDa and LPDb may include the same material as the landing pad LP. For example, the landing patterns LPDa and LPDb may include a metal material such as tungsten, titanium or tantalum.

The landing patterns LPDa and LPDb described herein may be dummy landing pads, which may not have any electrical connection to any of the integrated circuits of the semiconductor device according to embodiments of the inventive concept. However, the dummy landing pads LPDa and LPDb may have the same or similar structure and/or shape as the normal landing pad LP of the semiconductor device, including being formed of the same material (e.g., formed of the same material layer at the same level). For example, upper surfaces of the dummy landing pads LPDa and LPDb and the landing pad LP of the semiconductor device may be coplanar. The dummy landing pads may not be used to convey signals or power (unlike normal landing pads which are connected to internal circuitry of the semiconductor chip to communicate signals and/or power). In some instances, the dummy landing pads may form all or part of an electrical node that is electrically floated (e.g., not electrically (directly or indirectly) connected to any other conductor). In some examples, the dummy landing pads and the normal landing pads may be covered by the same insulating layer that is then patterned to expose the dummy chip pads and the normal chip pads. For example, the storage node contact BC may be electrically connected to the substrate, the landing pad LP may be provided on and electrically connected to the storage node contact BC, the data storage pattern DSP may be provided on and electrically connected to the landing pad LP, and the landing patterns LPDa and LPDb may not have any electrical connection to any of the integrated circuits functioning during the normal operation of the semiconductor device.

In a manufacturing process, The dummy patterns (or landing patterns) LPDa and LPDb may be used to reduce non-uniformities in a photolithography process (e.g., loading effect), which is caused by irregular pattern density across different regions. According to some embodiments of the invention, there may be two types of dummy patterns (e.g., first landing pattern LPDa and second) landing pattern LPDb in the interface region IA. For example, the first landing pattern LPDa may be useful to reduce the variation of the depth of recessed regions formed in the third capping layer 353L, which may be induced by an etching process to form the landing pad LP. The second landing pattern LPDb may be useful to reduce an etch damage to the first bit line sidewall BL_SW, which may be induced by an etching process to form the landing pad LP.

Although each of the first landing pattern LPDa and second landing pattern LPDb are illustrated in FIG. 4 as a single body extending in the second direction D2, in some embodiments, a plurality of each of the first landing patterns LPDa and second landing patterns LPDb may be arranged in a series (or in a row) extending in the second direction D2, and the plurality of each of the first landing patterns LPDa and second landing patterns LPDb may be spaced apart from each other.

The first landing pattern LPDa may cross more bit lines BL than the second landing pattern LPDb. The first landing pattern LPDa may be provided on the first bit line BL1 and the second bit line BL2 to cross the first bit line BL1 and the second bit line BL2. The second landing pattern LPDb may not be provided on the first bit line BL1, and thus may cross only the second bit line BL2.

The second landing pattern LPDb may be provided on the poly portion POL and the fence portion FNC. The second landing pattern LPDb may vertically overlap at least any one of the poly portion POL or the fence portion FNC. A bottom surface of the second landing pattern LPDb may be in contact with any one of an upper surface of the poly portion POL and an upper surface of the fence portion FNC. In addition, the first landing pattern LPDa may be spaced apart from the poly portion POL and the fence portion FNC in the first direction D1 not to vertically overlap the same.

On a plan view, the second landing pattern LPDb may be located between the first landing pattern LPDa and the contact plug CP. The second landing pattern LPDb may be provided on the bit line pad PD connected to the second bit line BL2. The second landing pattern LPDb may vertically overlap at least a portion of the bit line pad PD to cross the bit line pad PD.

For another example, a third landing pattern spaced apart from the first and second landing patterns LPDa and LPDb in the first direction D1 may be additionally provided. A number of the landing patterns may be two or more. However, any of them may not vertically overlap an end portion (or end) of the bit line BL. For example, the third landing pattern may be located between the second landing pattern LPDb and the contact plug CP.

A width W1 of the first landing pattern LPDa may be different from a width W2 of the second landing pattern LPDb. For example, the width W1 of the first landing pattern LPDa may be greater than the width W2 of the second landing pattern LPDb. A height (thickness in a vertical direction) of the first landing pattern LPDa may be smaller than a height of the second landing pattern LPDb. A maximum height of the first landing pattern LPDa may be smaller than a maximum height of the second landing pattern LPDb.

The first landing pattern LPDa may be provided on the bit line capping pattern 350 to vertically overlap the bit line capping pattern 350. In addition, the second landing pattern LPDb may not vertically overlap the bit line capping pattern 350. The second landing pattern LPDb may be spaced apart from the bit line capping pattern 350 in the first direction D1.

A landing insulating pattern LIP may be interposed between the first landing pattern LPDa and the second landing pattern LPDb. The first landing pattern LPDa and the second landing pattern LPDb may be spaced apart from each other in the first direction D1 by the landing insulating pattern LIP. The landing insulating pattern LIP may at least partially and vertically overlap the first bit line BL1. The landing insulating pattern LIP may include an insulating material. The landing insulating pattern LIP may include the same material as the interlayered insulating layer IL. The landing insulating pattern LIP may include at least one of silicon oxide, silicon nitride, silicon oxynitride or a combination thereof. For another example, the landing insulating pattern LIP may include an empty space (e.g., an air gap) including an air layer.

An upper surface of the first landing pattern LPDa may be located at the substantially same level as an upper surface of the second landing pattern LPDb. A bottom surface of the second landing pattern LPDb may be located at a lower level than a bottom surface of the first landing pattern LPDa. The bottom surface of the second landing pattern LPDb may be located at the substantially same level as a bottom surface of the landing insulating pattern LIP. The bottom surface of the landing insulating pattern LIP may be located at a lower level than the bottom surface of the first landing pattern LPDa.

The first bit line BL1 may include a first end portion EG1 adjacent to the landing patterns LPDa and LPDb. The first end portion EG1 of the first bit line BL1 may not vertically overlap the landing patterns LPDa and LPDb. On a plan view, the first end portion EG1 of the first bit line BL1 may be located between the first landing pattern LPDa and the second landing pattern LPDb. The first end portion EG1 may vertically overlap the landing insulating pattern LIP.

The first end portion EG1 may include a first bit line sidewall BL_SW. The first landing pattern LPDa may include a first landing sidewall LP_SW1 adjacent to the second landing pattern LPDb, and the second landing pattern LPDb may include a second landing sidewall LP_SW2 adjacent to the first landing pattern LPDa. The first landing sidewall LP_SW1 and the second landing sidewall LP_SW2 may face each other.

The first end portion EG1 may be located between the first landing sidewall LP_SW1 and the second landing sidewall LP_SW2. The first bit line sidewall BL_SW of the first end portion EG1 may be located between the first landing sidewall LP_SW1 and the second landing sidewall LP_SW2. The first bit line sidewall BL_SW may be shifted from each of the first landing sidewall LP_SW1 and the second landing sidewall LP_SW2 in a horizontal direction.

A shortest distance in the first direction D1 between the first landing sidewall LP_SW1 and the second landing sidewall LP_SW2 may be defined as a first interval SP1. The first interval SP1 may be a shortest distance in the first direction D1 between the first landing pattern LPDa and the second landing pattern LPDb. The first interval SP1 may be a width in the first direction D1 of the landing insulating pattern LIP. A shortest distance in the first direction D1 between the second landing sidewall LP_SW2 and the first bit line sidewall BL_SW of the first end portion EG1 may be defined as a second interval SP2. The first interval SP1 may be greater than the second interval SP2.

A landing spacer LPS may be provided on the first bit line sidewall BL_SW of the first bit line BL1 and on a side surface of the bit line capping pattern 350. The landing spacer LPS may extend onto an upper surface of the element separation pattern 120 to be provided under a bottom surface of the poly portion POL. The fence portion FNC may penetrate the landing spacer LPS. The landing spacer LPS may be interposed between the first bit line BL1 and the poly portion POL to prevent electrical connection therebetween. The landing spacer LPS may include an insulating material. However, for another example, the landing spacer LPS may be omitted so that the first bit line BL1 and the poly portion POL are in contact with each other.

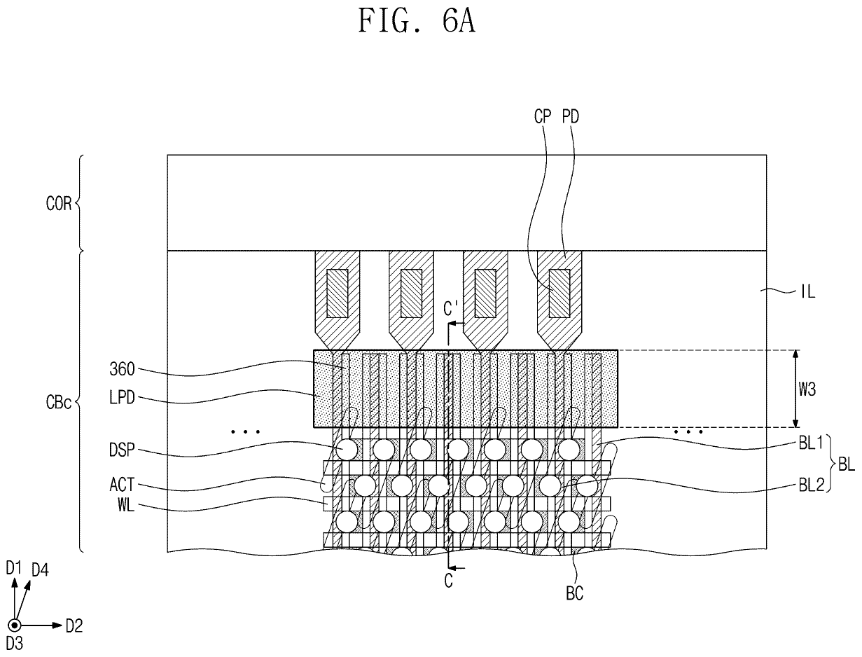

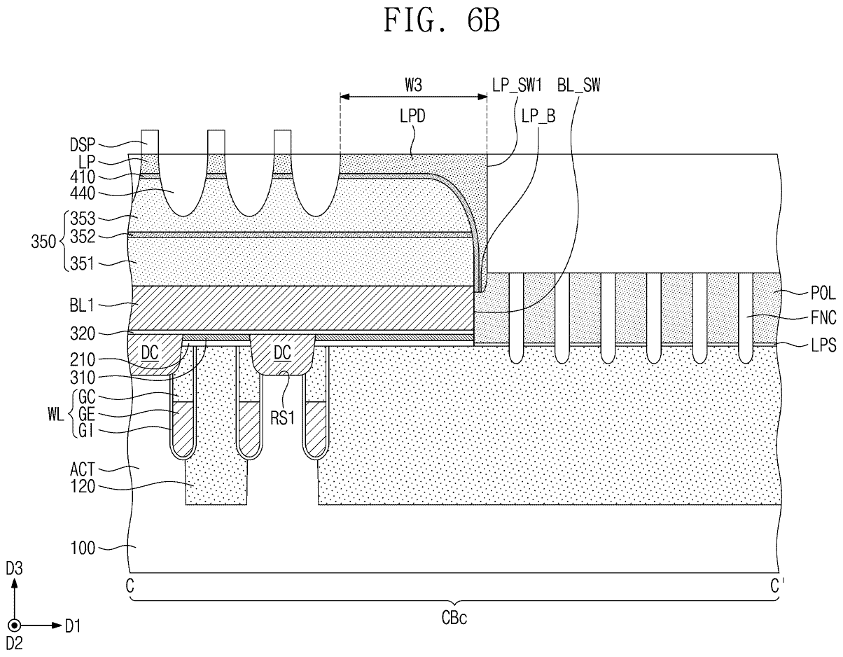

FIG. 6A is a plan view illustrating the cell block region of FIG. 3 as a diagram illustrating a semiconductor device according to comparative examples of the inventive concept. FIG. 6B is a cross-sectional view corresponding to line C-C′ of FIG. 6A. Comparative examples according to the inventive concept will be described with reference to FIGS. 6A and 6B in more detail. Duplicate technological features of those described with reference to FIGS. 3 to 5C will be omitted.

It is to be understood that both the examples and comparative examples described herein are intended to illustrate the present invention and should not be construed as limiting the scope of the invention in any way. The comparative examples are provided for the purpose of better understanding certain advantages and distinguishing features of the invention, and thus, are considered to be part of the present disclosure.

Referring to FIGS. 6A and 6B, a landing pattern LPD may be provided on the cell block region CBc in singularity, not in plurality. A width W3 of the landing pattern LPD may be greater than widths W1 and W2 of the landing patterns LPDa and LPDb of FIG. 4. Accordingly, the landing pattern LPD may vertically overlap the first end portion EG1 of the first bit line BL1. The landing pattern LPD may be a dummy pattern. For example, in a manufacturing process, the dummy pattern may be used to reduce non-uniformities in the photolithography process (e.g., loading effect), which is caused by irregular pattern density across different regions. For example, the dummy pattern LPD may help reduce the variation of the depth of recessed regions formed in the third capping layer 353L, which may be induced by an etching process to form the landing pad LP.

The landing pattern LPD may extend along an upper surface of the bit line capping pattern 350. The landing pattern LPD may be provided on the first barrier pattern 410, but the first barrier pattern 410 may be omitted. A bottom surface LP_B of the landing pattern LPD may be located at a lower level than an upper surface of the poly portion POL. The bottom surface LP_B of the landing pattern LPD may be located at a lower level than an upper surface of the bit line BL. The bottom surface LP_B of the landing pattern LPD may be in contact with the bit line sidewall BL_SW of the first bit line BL1. In this case, the landing spacer LPS (shown in FIG. 5C) may be omitted so that electrical interference and an electrical short circuit may occur between the landing pattern LPD and the bit line BL and between the poly portion POL and the bit line BL. As a result, electrical characteristics and reliability of the semiconductor device may be deteriorated. In some embodiments, though not shown in the drawings, the landing spacer LPS may be used in the manner illustrated in FIG. 5C to minimize the contact between the bit line sidewall BL_SW of the first bit line BL1 and the landing pattern LPD. Accordingly, while, the landing pattern LPD vertically (or in a plan view) overlaps the first end portion EG1 of the first bit line BL1, the landing pattern LPD may be spaced apart from the first end portion EG1 of the first bit line BL1 by the landing spacer LPS (for example, in a cross sectional view).

In addition, according to the inventive concept, the first end portion EG1 of the first bit line BL1 may not vertically overlap the landing patterns LPDa and LPDb. The first end portion EG1 of the first bit line BL1 may be interposed between the first landing pattern LPDa and the second landing pattern LPDb. Since the first end portion EG1 of the first bit line BL1 vertically overlaps the landing insulating pattern LIP to be spaced apart from the second landing pattern LPDb in the first direction D1, the first bit line BL1 may not be in contact with the landing patterns LPDa and LPDb. Accordingly, electrical interference and an electrical short circuit between the first bit line BL1 and the landing patterns LPDa and LPDb may be prevented or suppressed.

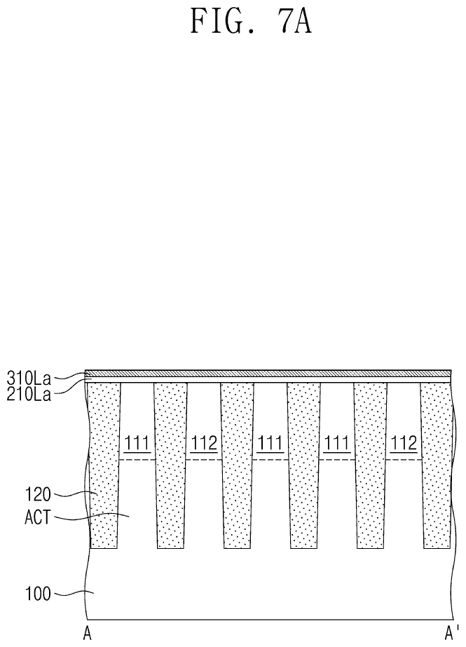

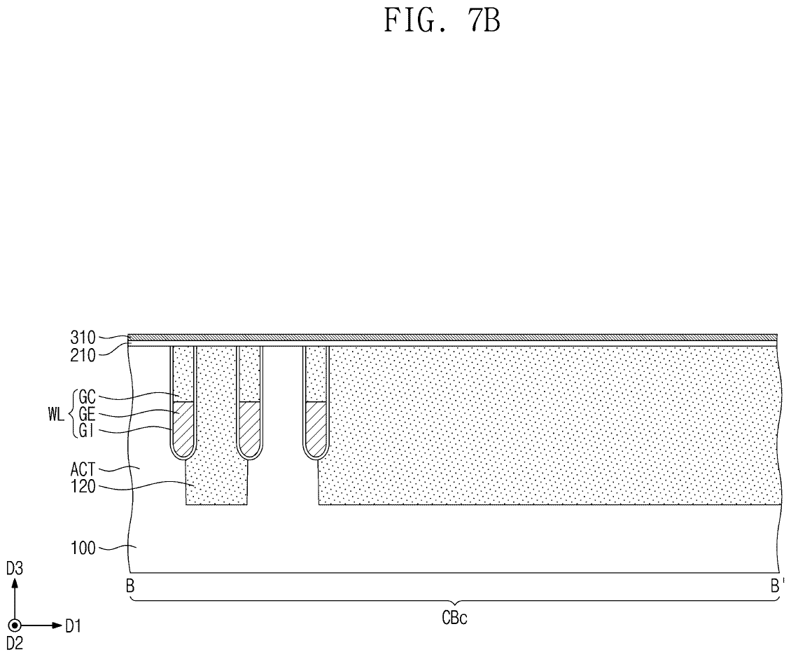

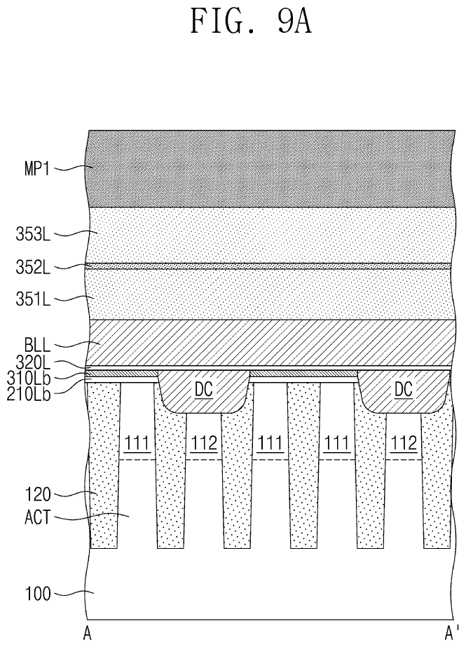

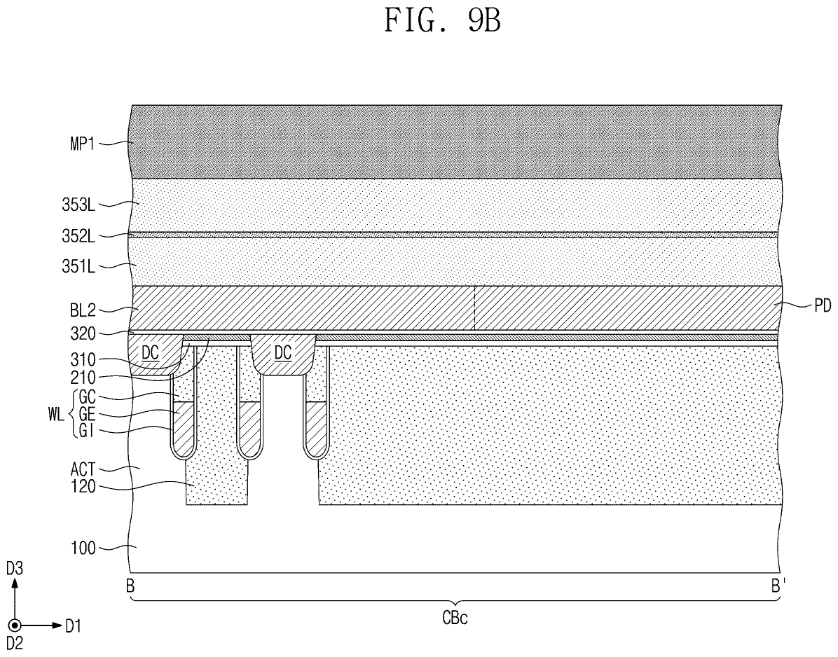

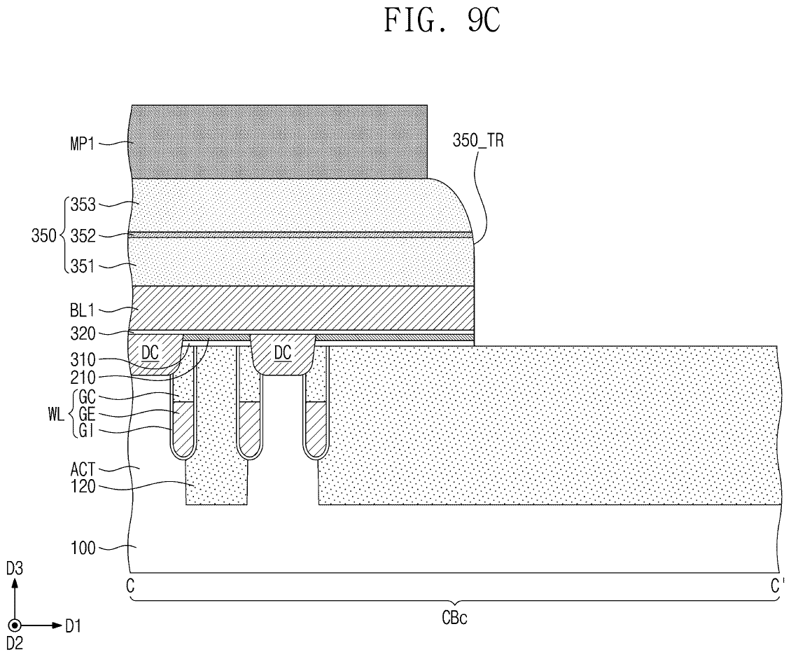

FIGS. 7A to 12C are diagrams illustrating a method for manufacturing a semiconductor device according to embodiments of the inventive concept. More specifically, FIGS. 7A, 8A, 9A and 12A are cross-sectional views corresponding to line A-A′ of FIG. 4. FIGS. 7B, 8B, 9B, 10A, 11A and 12B are cross-sectional views corresponding to line B-B′ of FIG. 4. FIGS. 9C, 10B, 11B and 12C are cross-sectional views corresponding to line C-C′ of FIG. 4.

Hereinafter, the method for manufacturing a semiconductor device according to some embodiments of the inventive concept will be described with reference to FIGS. 7A to 12C. In order to simplify description, duplicate descriptions of those made above will be omitted, and differences from those made above will be mainly described.

Referring to FIGS. 7A and 7B, the substrate 100 including the cell block region CB may be prepared. The element separation pattern 120 and the active pattern ACT may be formed on the substrate 100. Forming the element separation pattern 120 and the active pattern ACT may include forming a groove in the substrate 100 through patterning, and forming the element separation pattern 120 by filling the groove with an insulating material. The active pattern ACT may include a region, in which the groove is not formed, of the substrate 100.

The word lines WL may be formed in trenches formed in an upper portion of the substrate 100. Forming the word lines WL may include forming mask patterns on the active patterns ACT and the element separation pattern 120, forming the trenches by performing an anisotropic etching process by using the mask patterns, and filling the trenches with the word lines WL. The word lines WL may be spaced apart from each other in the first direction D1, and may extend in the active patterns ACT in the second direction D2. For example, filling the word lines WL may include conformally depositing the gate dielectric pattern GI on an inner surface of each of the trenches, filling insides of the trenches with a conductive layer, forming the gate electrode GE through an etch-back process and/or a grinding process of a conductive layer, and forming, on the gate electrode GE, the gate capping pattern GC that fills remaining portions of the trenches. A pair of word lines WL may cross the active pattern ACT, and the center portion 112 of the active pattern ACT defined between the pair of word lines WL may be defined. Remaining parts of the active pattern ACT spaced apart from the center portion 112 with each of the pair of word lines WL therebetween may be defined as the edge portions 111.

A first buffer layer 210La and a first polysilicon layer 310La may be sequentially formed on the substrate 100. The first buffer layer 210La and the first polysilicon layer 310La may cover an upper surface of the active pattern ACT, an upper surface of the element separation pattern 120, and an upper surface of the word line WL.

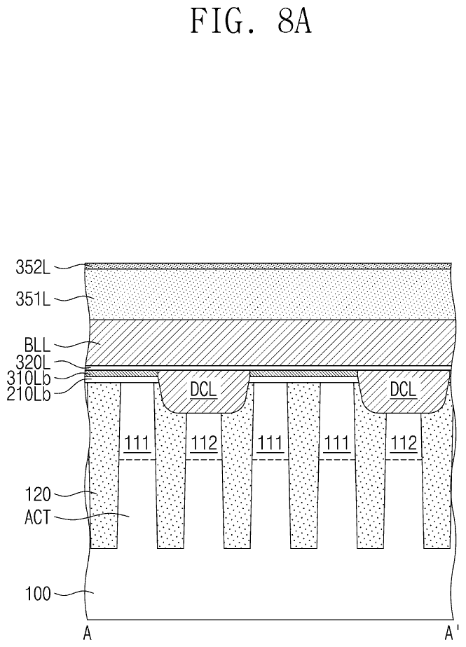

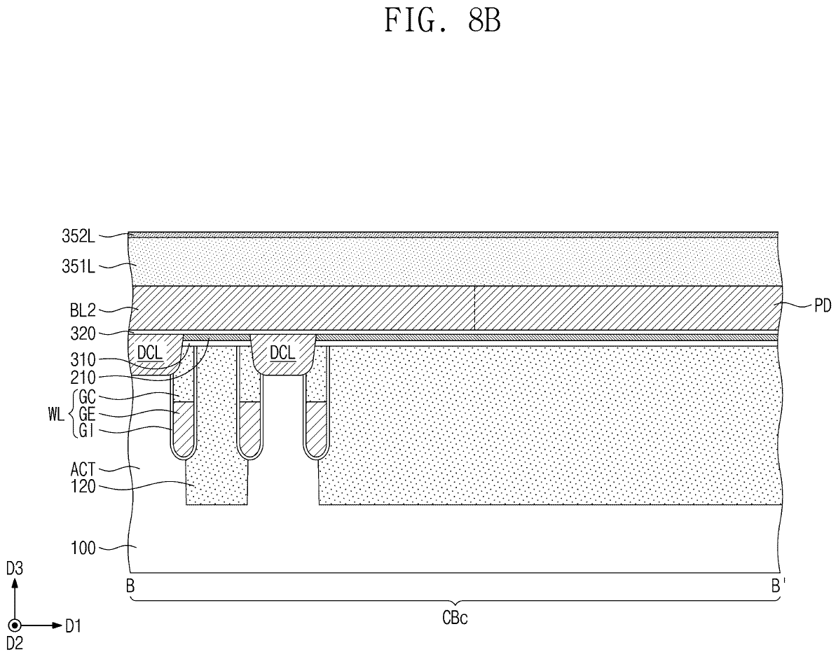

Referring to FIGS. 8A and 8B, the first recess region RS1 may be formed on an upper portion of the active pattern ACT. The first recess region RS1 may be provided in plurality. The first recess regions RS1 may be spaced apart from each other in the first and second directions D1 and D2. The first recess region RS1 may be formed on the center portion 112 of the active pattern ACT. Forming the first recess region RS1 may include performing an anisotropic etching process. A second buffer layer 210Lb and a second polysilicon layer 310Lb may be respectively formed from the first buffer layer 210La and the first polysilicon layer 310La through the anisotropic etching process. The first recess region RS1 may partially expose each of the center portion 112, the element separation pattern 120 and the gate capping pattern GC to an outside.

A preliminary bit line contact DCL may be formed so as to fill the first recess region RS1. The preliminary bit line contact DCL may be provided in plurality, and the preliminary bit line contacts DCL may be respectively formed on the center portions 112 of the active patterns ACT. An upper surface of the preliminary bit line contact DCL may be formed at the substantially same height as an upper surface of the second polysilicon layer 310Lb, and the upper surface of the preliminary bit line contact DCL may be coplanar with the upper surface of the second polysilicon layer 310Lb.

A first barrier layer 320L, a bit line layer BLL, a first capping layer 351L, a second capping layer 352L and a third capping layer 353L may be sequentially formed on the preliminary bit line contact DCL and the second polysilicon layer 310Lb. The first barrier layer 320L, the bit line layer BLL, the first capping layer 351L, the second capping layer 352L and the third capping layer 353L may entirely cover the cell block region CB, the surrounding region PER and SL and the core regions COR of the substrate 100.

Referring to FIGS. 9A to 9C, a first mask pattern MP1 may be provided on the third capping layer 353L. An etching process may be performed on the first buffer layer 210La, the first polysilicon layer 310La, the first barrier layer 320L, the bit line layer BLL, the first capping layer 351L, the second capping layer 352L and the third capping layer 353L by using the first mask pattern MP1 as a mask. Each of the first buffer layer 210La, the first polysilicon layer 310La, the first barrier layer 320L, the bit line layer BLL, the first capping layer 351L, the second capping layer 352L and the third capping layer 353L may be partially selectively removed in the etching process. The element separation pattern 120 may be exposed in the etching process. An exposed part of the element separation pattern 120 may be a part to form the poly portion POL and the fence portion FNC.

The bit line layer BLL may be partially etched to form the first end portion EG1 of the first bit line BL1. Each of the first to third capping layers 351L, 352L and 353L may be partially etched to respectively form the first to third capping patterns 351, 352 and 353. The formed first to third capping patterns 351, 352 and 353 may constitute the bit line capping pattern 350. The bit line capping pattern 350 may include a sidewall of a capping pattern trench 350_TR formed in the etching process. The sidewall of the capping pattern trench 350_TR may extend in a vertical direction, and may have a cross-section having a curved form.

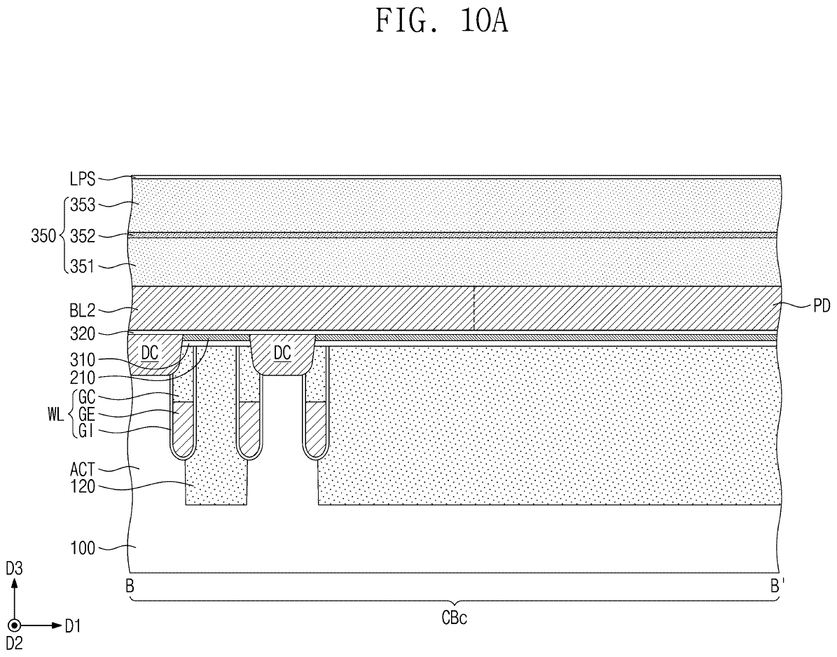

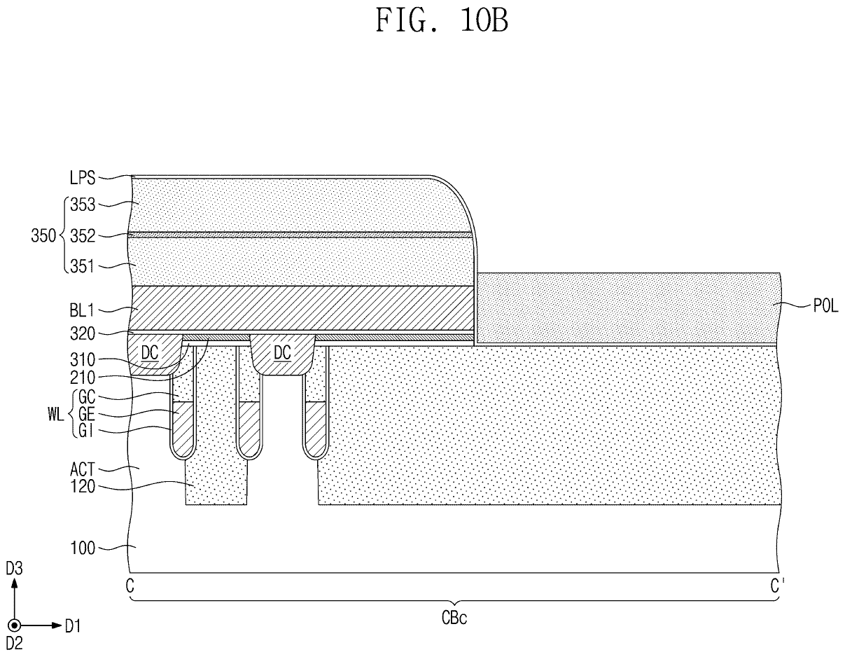

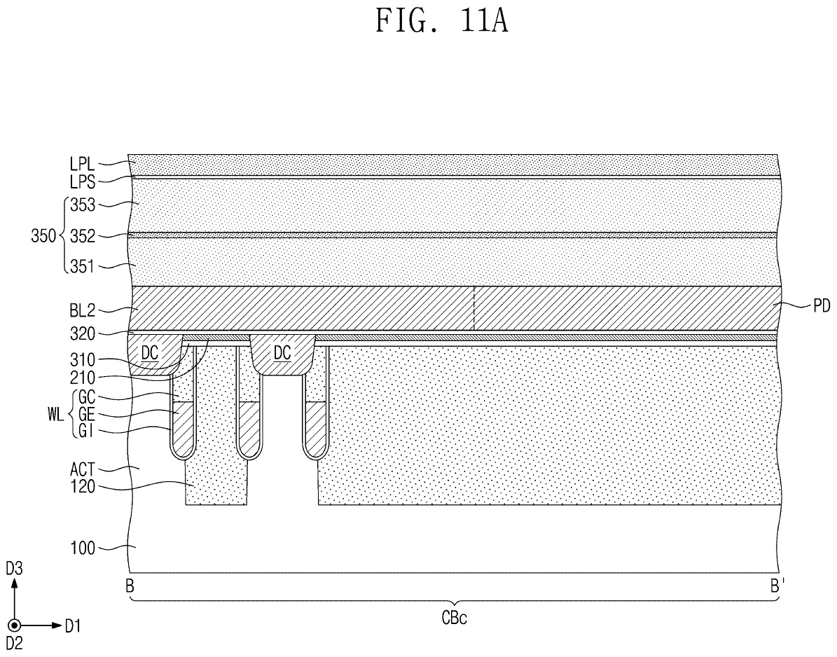

Referring to FIGS. 10A and 10B, the first mask pattern MP1 may be removed, and the landing spacer LPS may be conformally formed. The landing spacer LPS may cover an upper surface of the third capping pattern 353, the sidewall of the capping pattern trench 350_TR, and an upper surface of the exposed element separation pattern 120. The landing spacer LPS may include an insulating material. For example, the landing spacer LPS may include at least one of silicon oxide, silicon nitride, silicon oxynitride or a combination thereof.

The poly portion POL may be formed on the landing spacer LPS. The poly portion POL may have a greater height than the bit line BL. The poly portion POL may have a higher upper surface than the bit line BL, but the inventive concept is not limited thereto. For another example, the poly portion POL may have a lower upper surface than the bit line BL. The poly portion POL may not be formed on the bit line BL and the bit line capping pattern 350. The poly portion POL may include a conductive material.

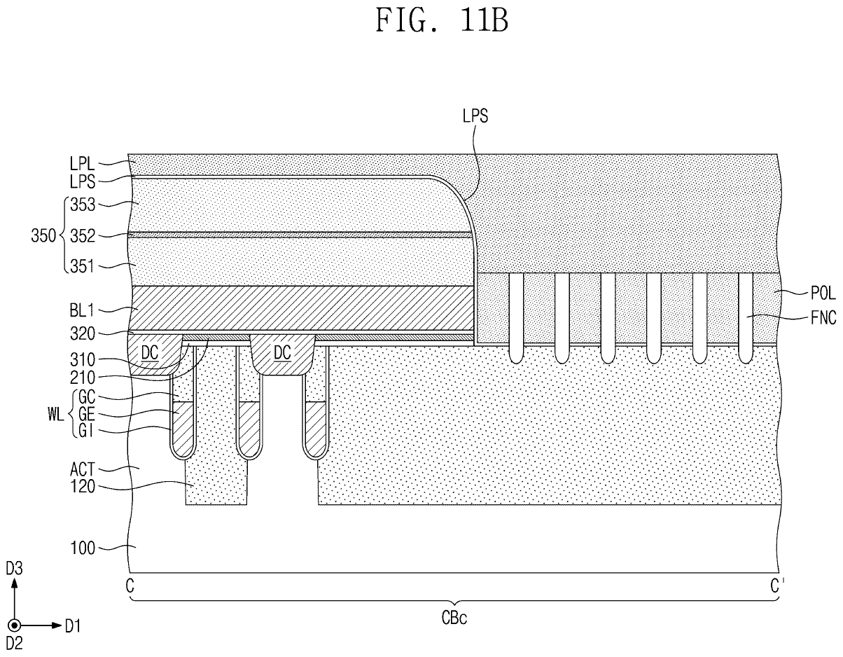

Referring to FIGS. 11A and 11B, a plurality of fence portions FNC may be formed between the poly portions POL. The fence portions FNC may vertically penetrate the poly portion POL. The fence portions FNC may penetrate the landing spacer LPS to extend into the element separation pattern 120. The fence portions FNC may include an insulating material, and may be provided between the poly portions POL to block electrical connection.

A landing pad layer LPL may be formed on a front surface of the cell block region CBc. The first barrier pattern 410 may be formed before the landing pad layer LPL is formed. The landing pad layer LPL may cover an upper surface of each of the landing spacer LPS, the poly portion POL and the fence portion FNC. In the landing pad layer LPL, a height of a part formed on the poly portion POL and the fence portion FNC may be greater than a height of a part formed on the bit line capping pattern 350. The landing pad layer LPL may include a metal material such as tungsten, titanium or tantalum.

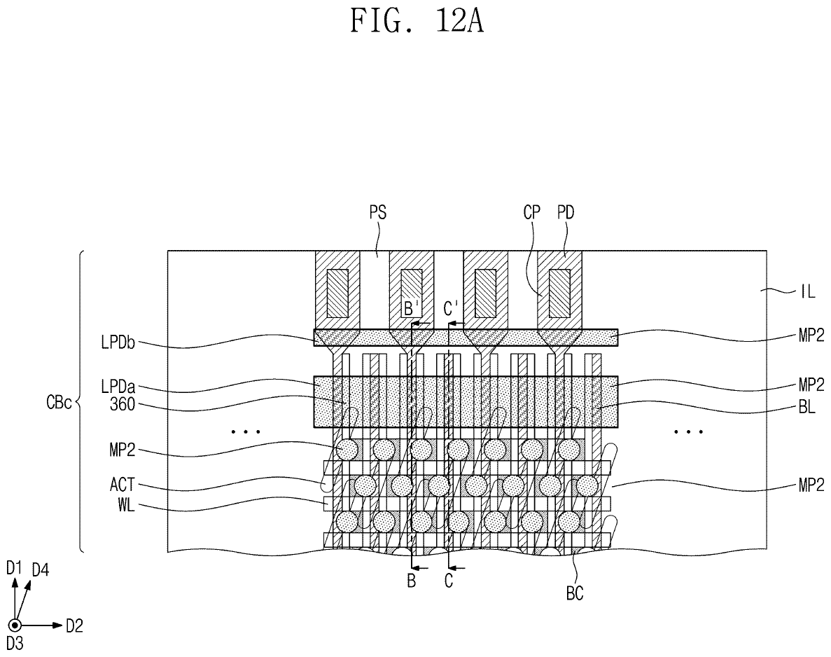

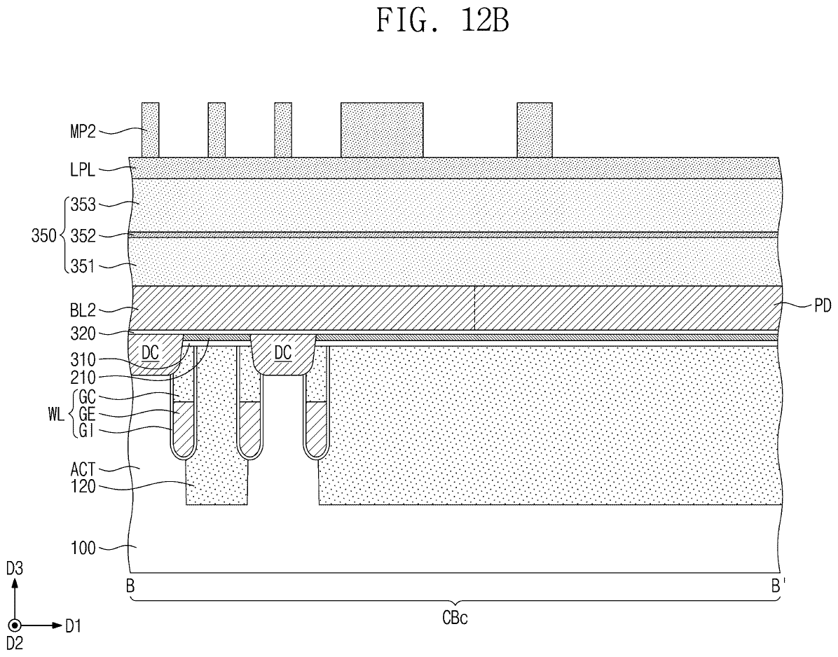

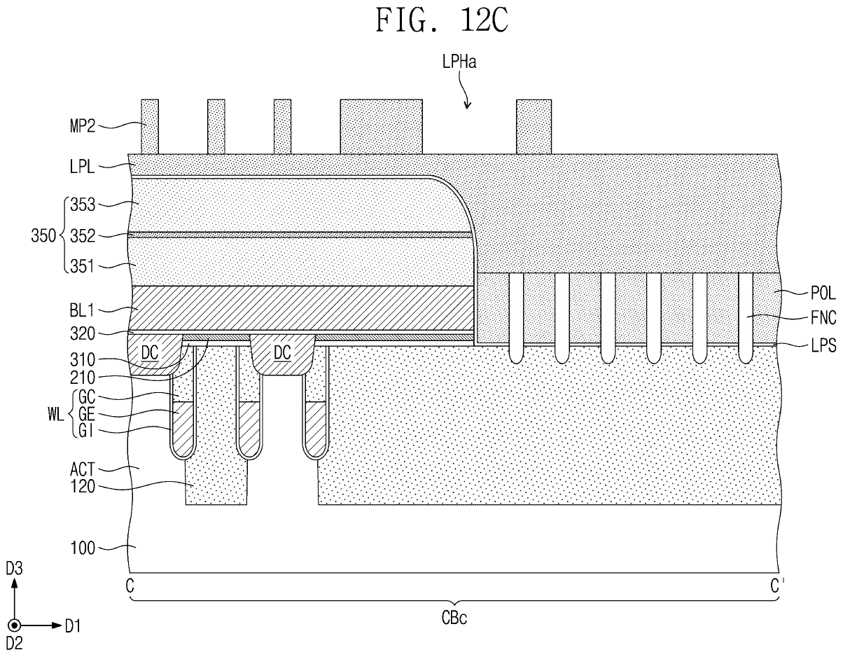

Referring to FIGS. 12A to 12C, a second mask pattern MP2 may be formed on the cell block region CBc. The second mask pattern MP2 may be formed on a part on which the landing patterns LPDa and LPDb of FIG. 4 are formed, and on a part on which the landing pad LP is formed. An etching process may be performed on the landing pad layer LPL by using the second mask pattern MP2 as a mask. The landing spacer LPS may be partially etched in the etching process. However, the poly portion POL and the fence portion FNC may not be removed.

The landing pad layer LPL may be partially etched to form insulating holes. The landing pad layer LPL may be etched to form the first landing pattern LPDa and the landing pad LP. The bit line capping pattern 350 may be exposed by first insulating holes. The poly portion POL and the fence portion FNC may be exposed by second insulating holes. Depths of the first insulating holes may be shallow than depths of the second insulating holes. A third insulating hole LPHa may expose an end portion of the first bit line BL1.

The filling pattern 440, the landing insulating pattern LIP and the interlayered insulating layer IL may be formed by filling the insulating holes with an insulating material. Specifically, the filling pattern 440 may be formed by filling the first insulating holes with the insulating material. The interlayered insulating layer IL may be formed by filling the second insulating hole with the insulating material. The landing insulating pattern may be formed by filling the third insulating hole with the insulating material. The filling pattern 440 may be formed so as to cover exposed parts of the landing pads LP and the contact plugs CP and to surround each of them.

The contact plug CP may be formed on the bit line pad PD. Forming the contact plug CP may include forming a contact hole on the bit line pad PD, forming a contact plug layer that fills the contact hole, and forming the contact plug CP by etching the contact plug layer. For example, the contact plug CP may be formed together with the landing pad layer and the second landing pattern LPDb.

The data storage pattern DSP may be formed on each of the landing pads LP. The contact wires may be formed on the contact plug CP.

According to the inventive concept, landing patterns crossing bit lines may be provided on a cell block region. In this case, an end portion of the bit line may be located between the landing patterns so that the end portion of the bit line may not vertically overlap the landing patterns. Accordingly, an electrical short circuit that occurs between the landing patterns and the end portion of the bit line may be prevented or suppressed. As a result, electrical characteristics and reliability of a semiconductor device may be improved.

The above description of embodiments of the inventive concept provides an example for description of the inventive concept. Therefore, the inventive concept is not limited to the above embodiments, and various modifications and changes such as combining the above embodiments may be made by those skilled in the art within the technical spirit of the inventive concept.

What is claimed is:

1. A semiconductor device comprising:
a substrate including a cell block region;
a first bit line extending on the cell block region in a first direction; and
landing patterns extending in a second direction crossing the first direction,
wherein the landing patterns include:
a first landing pattern crossing the first bit line; and
a second landing pattern spaced apart from the first landing pattern in the first direction, and
an end of the first bit line is located between the first landing pattern and the second landing pattern.

2. The semiconductor device of claim 1, wherein, in a first direction, the first landing pattern has a width different from a width of the second landing pattern.

3. The semiconductor device of claim 1, wherein the first landing pattern has a smaller thickness in a vertical direction than the second landing pattern.

4. The semiconductor device of claim 1, further comprising a bit line capping pattern on the first bit line,
wherein the first landing pattern vertically overlaps the bit line capping pattern, and
the second landing pattern is spaced apart from the bit line capping pattern in the first direction.

5. The semiconductor device of claim 1, further comprising a landing insulating pattern interposed between the first landing pattern and the second landing pattern.

6. The semiconductor device of claim 5, wherein the landing insulating pattern at least partially and vertically overlaps the first bit line.

7. The semiconductor device of claim 5, wherein a bottom surface of the landing insulating pattern is located at a lower level than a bottom surface of the first landing pattern.

8. The semiconductor device of claim 5, wherein a bottom surface of the landing insulating pattern is coplanar with a bottom surface of the second landing pattern.

9. The semiconductor device of claim 1, further comprising:
a second bit line extending in the first direction, and next to the first bit line in the second direction;
a bit line pad connected to the second bit line; and
a contact plug on the bit line pad,
wherein the second bit line is connected to the contact plug through the bit line pad, and
the second landing pattern is located between the first landing pattern and the contact plug.

10. The semiconductor device of claim 9, wherein the second landing pattern vertically overlaps at least a portion of the bit line pad.

11. A semiconductor device comprising:
a substrate including a cell block region;
a first bit line extending on the cell block region in a first direction; and
landing patterns extending in a second direction crossing the first direction,
wherein the landing patterns include:
a first landing pattern crossing the first bit line; and
a second landing pattern spaced apart from the first landing pattern in the first direction,
the first bit line includes a first end adjacent to the first landing pattern,
the second landing pattern is spaced apart from the first end in the first direction, and
the second landing pattern has a greater thickness in a vertical direction than the first landing pattern.

12. The semiconductor device of claim 11, further comprising a landing insulating pattern interposed between the first landing pattern and the second landing pattern.

13. The semiconductor device of claim 12, wherein the first end vertically overlaps the landing insulating pattern.

14. The semiconductor device of claim 12, wherein a bottom surface of the landing insulating pattern is located at a lower level than a bottom surface of the first landing pattern.

15. The semiconductor device of claim 11, further comprising:
a first interval defined as a shortest distance in the first direction between the first landing pattern and the second landing pattern; and
a second interval defined as a shortest distance in the first direction between the second landing pattern and the first end,
wherein the first interval is greater than the second interval.

16. A semiconductor device comprising:
a substrate including a cell block region;
a first bit line and a second bit line extending on the cell block region in a first direction, and being next to each other in a second direction crossing the first direction;
landing patterns extending in the second direction; and
a contact plug electrically connected to the second bit line,
wherein the landing patterns include:
a first landing pattern crossing the first bit line and the second bit line; and
a second landing pattern spaced apart from the first landing pattern in the first direction,
the first bit line includes a first end adjacent to the first landing pattern,
the second landing pattern is spaced apart from the first end in the first direction, and
the second landing pattern is located between the first landing pattern and the contact plug.

17. The semiconductor device of claim 16, wherein, in a first direction, the first landing pattern has a width different from a width of the second landing pattern.

18. The semiconductor device of claim 16, further comprising a landing insulating pattern interposed between the first landing pattern and the second landing pattern,
wherein the first end vertically overlaps the landing insulating pattern.

19. The semiconductor device of claim 18, wherein a bottom surface of the landing insulating pattern is located at a lower level than a bottom surface of the first landing pattern.

20. The semiconductor device of claim 16, further comprising a bit line pad connected to the second bit line,
wherein the second landing pattern vertically overlaps at least a portion of the bit line pad.
